(19) United States
(12) Patent Application Publication
(10) Pub. No.: US 2019/0219542 A1
(43) Pub. Date: Jul. 18, 2019

(54) HANDHELD PIPELINE INSPECTION TOOL WITH PLANAR EXCITATION COIL

(71) Applicant: Exxam Systems, LLC, Anchorage, AK (US)

(72) Inventors: Paul Lott, Anchorage, AK (US); Yuan Ji, Ames, IA (US)

(21) Appl. No.: 16/216,858

(22) Filed: Dec. 11, 2018

Related U.S. Application Data
(60) Provisional application No. 62/597,406, filed on Dec. 11, 2017.

(51) Int. Cl. G01N 27/82; H05K 1/16; G01M 3/40; G01R 33/02; G01R 33/00

(52) U.S. Cl. CPC G01N 27/82; H05K 1/165; H05K 2201/08; G01R 33/02; G01R 33/0094; G01M 3/40

(57) ABSTRACT

Apparatuses and methods for inspecting a section of pipe are disclosed. The apparatuses includes a handheld pipeline inspection tool that includes a planar excitation coil within a pad and an array of magnetometers disposed within a box attached to the pad. The excitation coil is formed from a plurality of loops of conductive traces printed on printed circuit board within the pad and the excitation coil is energized with an alternating current received from a power source within the box. The energized excitation coil generates a magnetic field that interacts with the section of pipe and the magnetometer array is used to detect variations in the magnetic field due to the presence of defects within the section of pipe.

### CROSS-REFERENCE TO RELATED APPLICATION(S)

This application claims the benefit of U.S. Provisional Patent Application No. 62/597,406 filed on Dec. 11, 2017, entitled HANDHELD PIPELINE INSPECTION TOOL WITH PLANAR EXCITATION COIL, which is incorporated herein by reference in its entirety.

### BACKGROUND

Inspection of various piping systems and pipelines for defects, cracks, corrosion, wear and the like is important for maintaining the integrity of such systems to avoid potentially catastrophic consequences from failure of pipes during use. In some applications, the piping systems are used to transport hot and/or corrosive materials. Often, such piping systems are provided with an exterior layer of insulation or the like that inhibits visual inspection of the piping system and conventional inspection systems that require direct access to the pipes. For example, piping systems used to transport petroleum products or the like over large distances often include a thick layer of polymeric insulation and an outer metal sheathing. Piping systems may also be coated or encased with a protective outer casing, such as a plastic or elastomeric outer jacket, and are extremely difficult and costly to effectively monitor for wear, corrosion, damage and similar defects.

Conventional pipeline inspection systems typically use insertable inspection probes called inline inspection pigs that are inserted directly into the pipe and travel along the pipe. An inspection pig may be self-propelled or may be carried through the pipe by the flow within the pipe. One obvious disadvantage of inspection pigs is that they require access to the interior of a pipe. For many pipe systems, accessing the pipe to insert the inspection pig can be problematic, as it typically requires shutting down the flow within the pipe, and some disassembly and/or use of an access port. Other pipe inspection systems may be arranged around the exterior surface of the pipeline and may utilize an induced magnetic field to inspect the pipe. These systems may be self-propelled using a wheel or track-mounted transportation system that pushes the inspection system down the length of the pipeline. However, these inspection systems are only usable on pipelines without bends and each inspection system is only usable for certain sizes of pipe. It would therefore be desirable to provide a pipeline inspection system that may be used for inspecting the condition of a pipe even when the pipe is not easily accessible by a conventional inspection system or when the pipe includes bends that inhibit the movement of the inspection system through the pipe, and that may be used for pipes of varying sizes.

### BRIEF DESCRIPTION OF THE DRAWINGS

FIG. 1 is an isometric view of a handheld pipeline inspection tool arranged over a section of a pipe configured in accordance with the present technology.

FIG. 2 is a side elevation view of the handheld pipeline inspection tool arranged over the section of the pipe configured in accordance with the present technology.

FIG. 3 is a bottom plan view of the handheld pipeline inspection tool configured in accordance with the present technology.

FIG. 4A is a side elevation view of the handheld pipeline inspection tool generating a magnetic field when the tool is arranged over a defect-free section of the pipe configured in accordance with the present technology.

FIG. 4B is a side elevation view of the handheld pipeline inspection tool generating a magnetic field when the tool is arranged over a section of the pipe having a defect configured in accordance with the present technology.

FIG. 5 is a flow chart describing the operation of the handheld pipeline inspection tool.

### DETAILED DESCRIPTION

A handheld pipeline inspection tool for inspecting a section of pipe is disclosed. The tool includes a planar pad mounted to a bottom surface of a central body. The pad includes an excitation coil that is energized by alternating current (AC) produced by an AC generator within the body. The energized excitation coil generates magnetic fields that interact with a section of pipe. An array of magnetometers within the body detects variations in the magnetic field due to the presence of defects within the adjacent section of pipe. In this fashion, the handheld pipeline inspection tool facilitates the inspection of pipelines in unusual configurations and hard to access conditions.

Various embodiments of the invention will now be described. The following description provides specific details for a thorough understanding and an enabling description of these embodiments. One skilled in the art will understand, however, that the invention may be practiced without many of these details. Additionally, some well-known structures or functions may not be shown or described in detail, so as to avoid unnecessarily obscuring the relevant description of the various embodiments. The terminology used in the description presented below is intended to be interpreted in its broadest reasonable manner, even though it is being used in conjunction with a detailed description of certain specific embodiments of the invention.

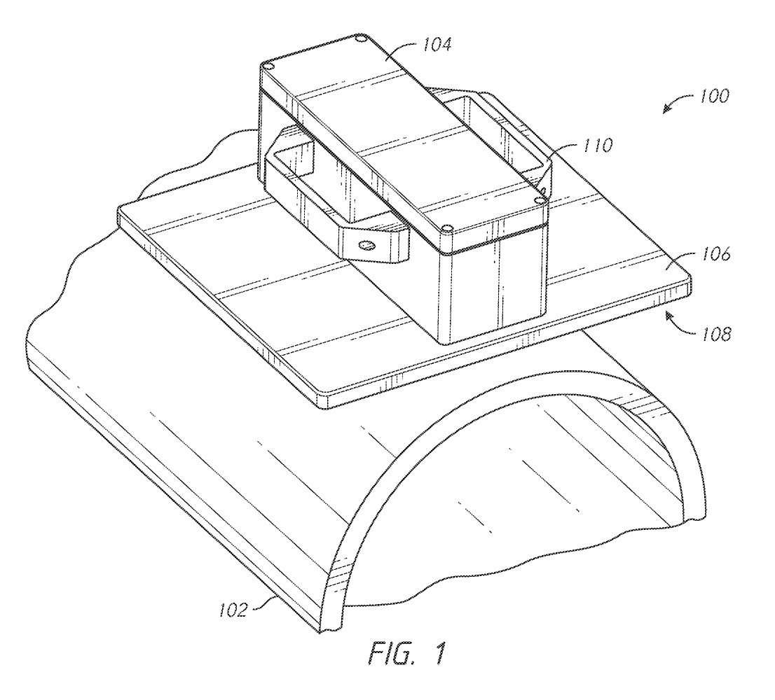

FIG. 1 is an isometric view of a handheld pipeline inspection tool 100 arranged over a section of pipe 102. The pipe 102, which may be formed from aluminum, stainless steel, corrugated galvanized metal, and/or any other metal, may include defects not visible on the surface of the pipe 102 but that are detectable using the tool 100. The tool 100 includes a central body 104 and a pad 106 coupled to a bottom surface of the body 104. Handles 110 are attached to the exterior surface of the body 104 such that a user of the tool may grasp the tool with the handles 110 and arrange the position of the tool 100 over the pipe 102 such that a bottom surface 108 of the pad 106 is adjacent to the pipe 102.

The body 104 includes an array of magnetometers (not shown) positioned near a bottom surface (not shown) of the body 104. When a user of the tool 100 desires to use tool 100 to test a section of the pipe 102, the user uses the handles 110 to position the body 104 over the pipe 102 such that the array of magnetometers is located directly over the pipe 102. The array of magnetometers is used to measure and detect the presence of magnetic fields in the section of pipe 102 under test. The pad 106 may be coupled to the bottom surface of the body 104 and exterior surfaces of both the pad 106 and the body 104 may be formed from a nonconductive material (e.g., plastic) that allows magnetic and electrical fields to propagate through the material with minimal interference or reduction in sensitivity. The use of nonconductive materials for the structural elements of the tool ensures that any magnetic fields that the array of magnetometers detects and measures are not affected by the exterior surfaces of the body 104 or pad 106.

Power is provided to the tool 100 either by an external power source via a power cable or by an internal rechargeable battery contained in the body. The body 104 includes a controllable alternating current (AC) generator (not shown) connected to pad 106 that provides an alternating current to an excitation coil (not shown) within the pad 106 in order to energize the coil. As will be discussed in greater detail below, energizing the excitation coil leads to the generation of a magnetic field by the coil. The magnetic fields extend outwards from the pad 106 inducing a magnetic field within the walls of the pipe 102 when the tool 100 is arranged over the pipe 102. In some embodiments, the alternating current has a low frequency, such as a frequency less than 100 Hz, less than 10 Hz, or even less than 5 Hz. However, the optimal frequency range will depend on the particular geometry and material properties of the pipe being examined. It is appreciated that one of ordinary skill in the art will be sufficiently able to identify a suitable frequency for a given section of piping depending on the pipe size and composition. Additional details about alternating current waveforms that may be used by the tool may be found in U.S. application Ser. No. 15/841,714, filed Dec. 14, 2017, entitled “EDDY CURRENT PIPELINE INSPECTION USING SWEPT FREQUENCY,” which is hereby incorporated by reference in its entirety.

The body 104 also includes a data acquisition system operatively connected to the array of magnetometers and the AC power supply. The data acquisition system may include one or more microprocessors or microcontrollers, sensors, and analog-to-digital converters to convert measured analog signals into digital representations of those signals. A representative data acquisition system is disclosed in the aforementioned U.S. application Ser. No. 15/841,714. The data acquisition system monitors the application of the AC power to the excitation coil in the pad 106 by the AC generator. As power is applied to the excitation coil, the data acquisition system receives sensor data from the array of magnetometers. As will be discussed in additional detail herein, the received sensor data may then be sent to a data processing system to determine if the pipe 102 includes any defects. The body may be operatively connected to a remote data processing system (e.g., a laptop) using either a wired or wireless connection. In some embodiments, all or a portion of the data processing system may be located within the body 104 such that at least some of the processing of the received sensor data is performed by the tool 100. After pre-processing the received sensor data, the body may transmit the pre-processed sensor data to the remote data processing system for further processing and analysis. In other embodiments, the body may not include a data processing system and the tool 100 may be configured to send the received sensor data from the data acquisition system to the remote data processing system without performing any initial processing.

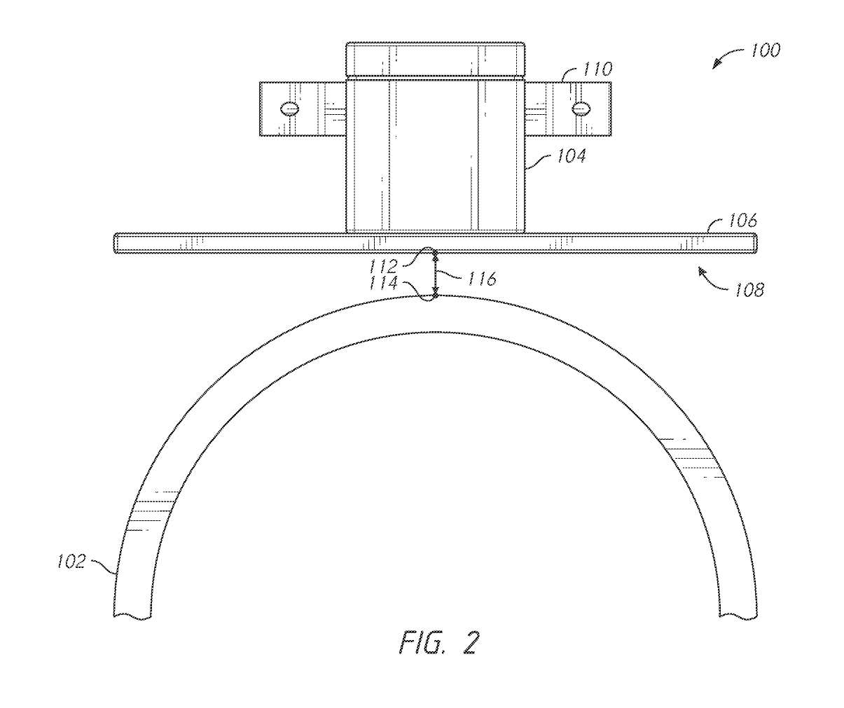

FIG. 2 is a side elevation view of the tool 100 arranged over the pipe 102. The central body 104 may be positioned over the pipe 102 such that a midpoint 112 of the bottom surface 108 of the pad 106 is separated by a distance 116 from a point 114 on the pipe 102. The body 104 may be positioned such that a line segment drawn from the midpoint 112 to the point 114 is perpendicular to the bottom surface 108 of the pad 106. When an alternating current from the AC generator is provided to the excitation coil within the pad 106, the energized excitation coil generates a magnetic field around the excitation coil and the generated magnetic field induces a magnetic field within the walls of the pipe 102, where the induced magnetic field has a strength inversely proportional to the distance between the pad 106 and the pipe 102 and directly proportional to the magnitude of the current provided to the excitation coil.

The array of magnetometers (not shown) are positioned along the bottom surface of the body 104. As will be discussed in greater detail below, the array of magnetometers is arranged along a line that intersects with the midpoint 112. When a user desires to use the tool 100 to examine the pipe 102 for defects, the user arranges the tool 100 such that the array of magnetometers is positioned over the point 114 and the midpoint 112 is separated from the point 114 by a distance 116. In some embodiments, the distance 116 may be 1 inch. However, this is merely an example. In other embodiments, the distance 116 may be less than 1 inch, between 1 and 2 inches, less than 4 inches, or between 5 and 10 inches. The desired distance is adjusted depending on the strength of the generated magnetic fields and the sensitivity of the array of magnetometers. Typically, positioning the body closer to the pipe will result in better resolution and accuracy in detecting pipe defects.

If the bottom surface 108 of the pad 106 is positioned too close to the exterior surface of the pipe 102 (i.e., if the excitation coil within the pad 106 is too close to the pipe 102), the magnetic fields induced within the pipe 102 by the excitation coil may not behave sufficiently well to allow for accurate detection of pipe defects. To prevent this, stand-off guides or pegs (not shown) may be attached to the bottom surface 108. The stand-off guides project perpendicularly from the bottom surface and extend a desired minimum distance that the pad is to remain separated from the external surface of the pipe. The purpose of the stand-off guides is to ensure that the bottom surface of the pad doesn't touch the surface of the pipe as a result of operator misalignment of the tool with the pipe. The stand-off guides may be formed of plastic or other non-conductive material that doesn't impair the magnetic fields generated by the excitation coil. In some embodiments, the height of the stand-off guides may be adjustable to allow the minimum desired distance to be configured depending on the particular pipe being tested.

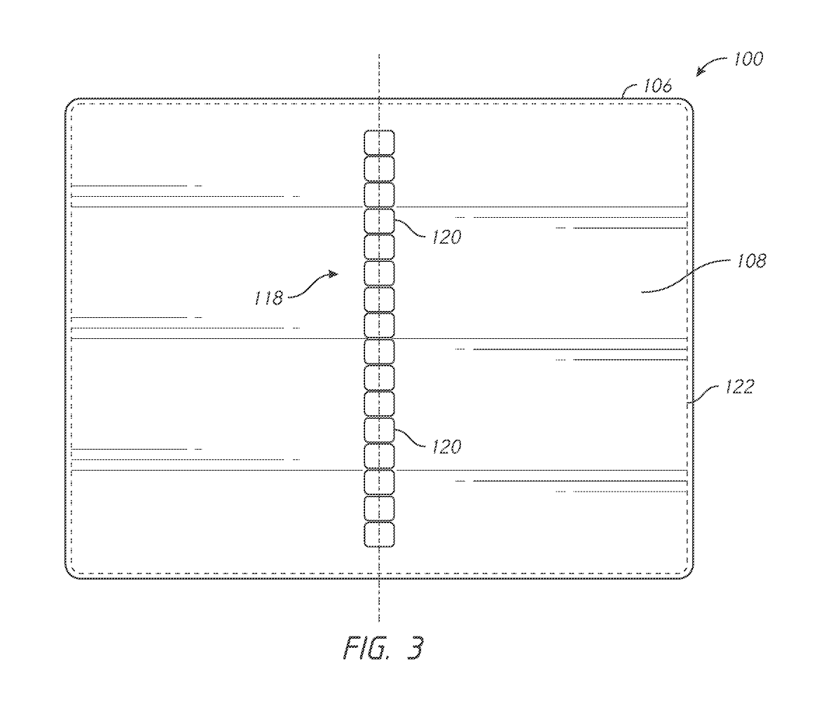

FIG. 3 is a bottom plan view of the tool 100. The pad 106 includes a conductive excitation coil 122 disposed around the perimeter of the pad 106 and arranged adjacent to the bottom surface 108 of the pad 106. The excitation coil may be encapsulated in the pad structure itself or may be affixed to the exterior surface of the pad 106. The excitation coil 122 is coupled to the AC generator within the body 104 and configured to receive an alternating current from the generator. An array 118 of magnetometers 120 is arranged adjacent to the bottom surface of the body 104 along a midline 124 (sometimes referred to as “center axis”). As previously discussed, the magnetometers 120 are configured to detect and measure magnetic fields induced within the pipe 102 (not shown) by the excitation coil 122.

In the embodiment shown in FIG. 3, the array 118 includes sixteen magnetometers 120 arranged in a 1×16 array positioned on or near the midline 124 of the bottom surface of the body 104. However, this is merely an example. In other embodiments, the tool 100 may include 32 magnetometers arranged in a 2×16 array, 36 magnetometers arranged in a 3×12 array, or 40 magnetometers arranged in a 4×10 array. In general, the tool 100 may include any desired number of magnetometers 120 arranged in any desired layout. In some embodiments, the magnetometers 120 in the array 118 may be vector magnetometer sensors, and more particularly, fluxgate magnetometer sensors. However, this is merely an example. In other embodiments, other types of magnetometers, such as magnetoresistive magnetometers (e.g., giant magnetoresistive or anisotropic magnetoresistive magnetometer sensors) may be used.

The excitation coil 122 includes at least one loop of conductive material disposed along the perimeter of the pad 106. The pad 106 may include a printed circuit board (PCB) having a plurality of traces printed onto the board. The traces may be formed from a conductive material (e.g., a metal such as copper) and may be printed around the edge of the PCB to form the at least one loop of conductive material. The PCB may have a size similar to the size of the pad 106 and may be arranged within the pad 106 such that the traces are positioned near the edge of the pad 106. In some embodiments, the excitation coil 122 includes 125 loops of conductive material formed from the conductive traces printed onto the PCB. However, this is merely an example. In other embodiments, the excitation coil 122 includes 100 loops, 150 loops, 50 loops, or any other desired number of loops.

Forming the excitation coil 122 from conductive traces printed onto a PCB is merely an example. If desired, the excitation coil 122 may be formed by a different structure. For example, the excitation coil 122 may be formed from loops of conductive and flexible wire disposed around the perimeter of the pad 106 or embedded within the pad. In general, the excitation coil 122 may be formed from any desired conductive material that can be energized with AC current.

During operation of the tool 100, the excitation coil 122 is energized with the alternating current generated by the AC generator. As is well known in the art, a moving charge (i.e., a current) generates a magnetic field. Applying a current to the conductive loops that form the excitation coil 122 will therefore generate a magnetic field around the excitation coil 122. When the tool 100 is arranged over the pipe 102 being examined, the generated magnetic field will propagate towards the pipe 102 and induce a magnetic field within the conductive portions of the pipe 102 (e.g., the metal sidewalls of the pipe 102) near the tool 100. The magnetometers 120 within the tool 100 are then used to detect and measure the induced magnetic field in the pipe 102.

At a given point near the energized loop, the magnetic field will have a given direction and a magnitude. The direction of the magnetic field is dependent on the position of the point relative to the loop and the polarity of the current used to energize the conductive material at any point in time. The strength of the magnetic field is dependent on the magnitude of current flowing through the excitation coils, the diameter and configuration of the excitation coils, and the distance between the loop and the point at which the magnetic field is measured. In embodiments where the current is an alternating current, the polarity of the electric field switches at regular intervals, causing the generated magnetic field to switch direction as well. For example, in embodiments where the current has a frequency of 10 Hz, the direction of the generated magnetic field may switch directions 10 times every second.

At a given point in time, the alternating current used to energize the excitation coil 122 shown in FIG. 3 may have a first polarity, causing the current to flow through the conductive loops of the excitation coil 122 in a counterclockwise direction. A current flowing in a counterclockwise direction leads to the generation of a magnetic field having a direction that points generally downwards, away from the bottom surface 108 of the pad 106. At a different point in time, the alternating current may have a second polarity such that current flows in a clockwise direction and the generated magnetic field has a direction that points generally upwards, towards the bottom surface 108 of the pad 106.

Each of the magnetometers 120 may have a direction of sensitivity along which the magnetometers 120 are most sensitive to the presence of a magnetic field. In embodiments where the magnetometers 120 are vector magnetometers, the magnetometers may have a vertical direction of sensitivity (i.e., perpendicular to the bottom surface 108 of the pad 106) such that each magnetometer 120 may only be capable of sensing magnetic fields having vertical component that are perpendicular to the bottom surface of the body 104. As a result, if the magnetic field at points below a given magnetometer 120 have directional components parallel to the bottom surface of the body 104 (i.e., the direction of the magnetic fields is not perpendicular to the bottom surface of the body 104), the horizontal component of the magnetic field will not be sensible to the given magnetometer 120 and the measured strength of the magnetic field is dependent on the perpendicular components of the magnetic fields.

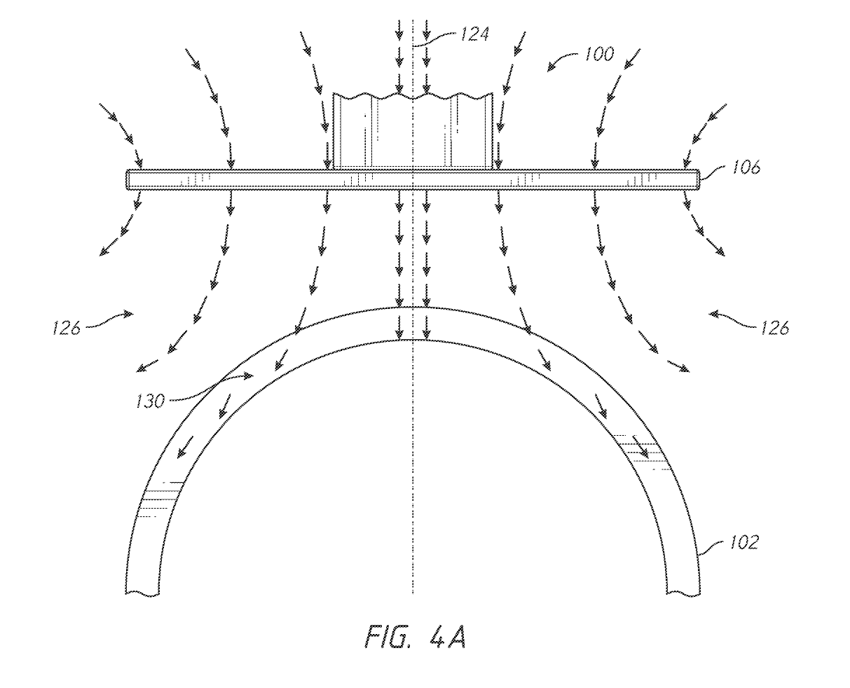

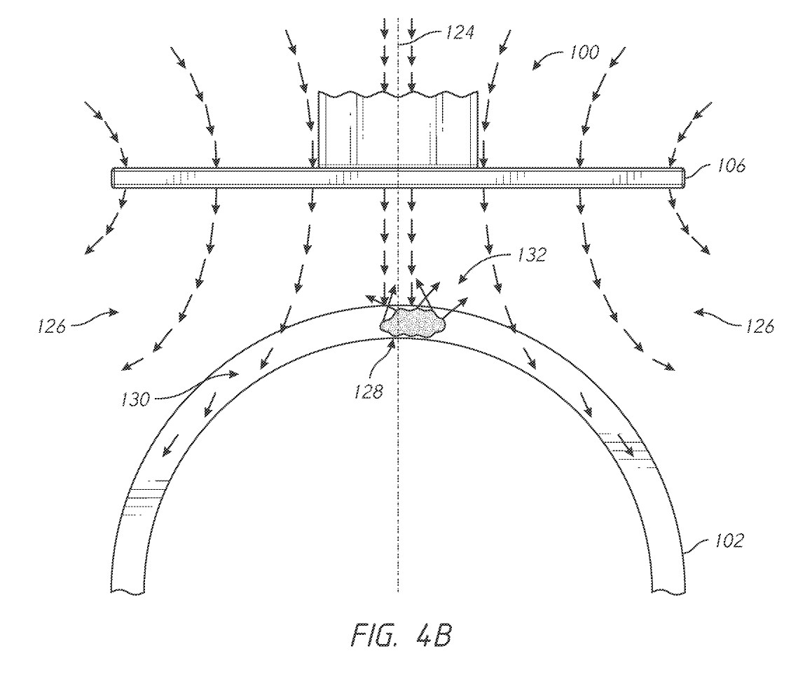

FIGS. 4A and 4B show side elevation views of the tool 100 arranged over the pipe 102. In FIG. 4A, the tool 100 is arranged over a section of the pipe 102 having no defects. The excitation coil within the pad 106 is energized with an alternating current such that the excitation coil within the pad 106 generates a magnetic field 126 around the tool 100 having a direction generally pointed downwards towards the pipe 102. The generated magnetic field 126 induces a magnetic field 130 within the walls of the pipe 102. The magnetometers, which are disposed within the tool 100 on or near midline 124, may be used to measure the magnetic field at points below the magnetometers (e.g., at points that fall on or near midline 124). At these points, the direction of the generated magnetic field 126 may be perpendicular to the bottom surface of the tool 100. Because the magnetic field at these points has a direction perpendicular to the bottom surface of the tool 100, the magnetometers may be capable of sensing the entire magnitude of the magnetic field at these points. At points farther away from the midline 124, the generated magnetic field 126 may have a directional component parallel to the bottom surface of the tool 100.

When the tool 100 is positioned over the pipe 102, the magnetic field 126 generated by the energized excitation coil within the pad 106 of the tool 100 induces a magnetic field 130 within the conductive walls of the pipe 102. In instances where the section of the pipe 102 being examined with the tool 100 is free from defects, the induced magnetic field 130 propagates through the metal in a predictable manner, generally having a decreased strength at points further from the source of the magnetic field (i.e., the excitation coil) and having a direction similar to the direction of the generated magnetic field at points near the section of pipe 102. However, the presence of defects within the pipe 102 causes the magnetic field 130 within the pipe 102 to deflect off of the defects, causing abnormalities in the propagation of the field through the pipe 102. This phenomenon is often referred to as magnetic flux leakage because the induced magnetic field “leaks” from the conductive material that forms the pipe 102.

In the situation shown in FIG. 4A, the pipe 102 includes no significant defects and the induced magnetic field 130 within the pipe 102 has a strength and direction similar to the strength and direction of the magnetic field 126 outside of the pipe. However, in the situation shown in FIG. 4B, the section of the pipe 102 being examined includes a defect 128. The presence of the defect 128 within the section of the pipe 102 leads to the magnetic fields 126 and 130 deflecting off of the defect 128, causing the generation of a deflected magnetic field 132. The deflected magnetic field 132 may have a directional component perpendicular to the bottom surface of the tool 100 and sensible by the magnetometers within the tool 100. In other words, the presence of the defect 128 within the pipe 102 leads to the formation of the deflected magnetic field 132. This deflected magnetic field 132 may have a vertical component sensible by the magnetometers within the tool 100.

In the embodiment shown in FIGS. 1-4B, the excitation coil 122 is formed within a single pad 106 coupled to the bottom surface of the body 104. In other embodiments, however, excitation coil may be formed as part of multiple pads rigidly coupled to each other. For example, the pipeline inspection tool may include three separate pads coupled to each other, where a first of the three pads is coupled to the bottom surface of the body of the tool and the other two pads are attached to opposing sides of the first pad, where the excitation coil is formed through each of the three pads.

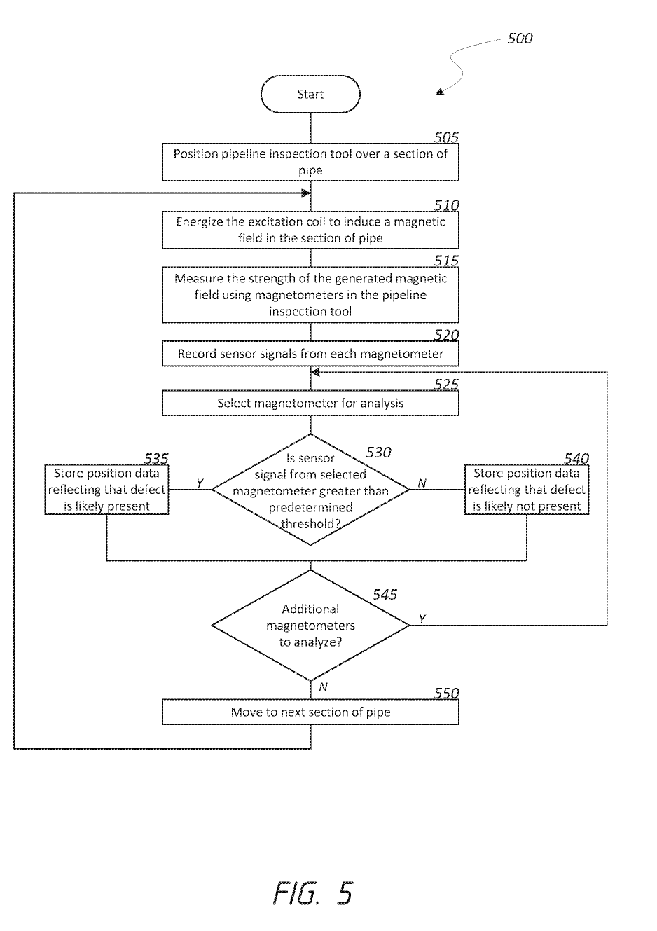

FIG. 5 shows a method 500 of using a pipeline inspection tool to detect the presence of defects within a pipe. At step 505, a user positions the pipeline inspection tool over a section of the pipe to check for defects, where positioning the pipeline inspection tool over a given section of pipe includes positioning the body such that the array of magnetometers is directly above the section of pipe to be tested and the bottom surface of the pad is spaced a given distance away from the surface of the pipe. The distance between the bottom surface of the pad and the pipe may be determined by the user and may be based on the strength of the magnetic fields generated by the tool, the size and structure of the pipe, and/or the material that the pipe is formed from.

At step 510, the excitation coil in the pad is energized with an alternating current generated by an AC generator in order to induce magnetic fields within the section of pipe.

At step 515, magnetometers in the pipeline inspection tool measure the strength of the induced magnetic field in the section of pipe over which the tool is positioned. The magnetometers may only be sensitive to the vertical component of the induced magnetic field (i.e., the component having a direction perpendicular to the bottom surface of the pad) such that, if the induced magnetic field does not have a vertical component, the magnetometers will not detect any magnetic field.

At step 520, a data acquisition system coupled to the magnetometers records sensor signals from each of the magnetometers. In some embodiments, the sensor values may be a simple indication of whether that magnetometer sensed a magnetic field at a given location. In other embodiments, the sensor value may also include the strength of the magnetic field measured by the magnetometers.

At step 525, a data processing system coupled to the data acquisition system selects one of the plurality of magnetometers for analysis and at step 530, the data processing system determines if the sensor signal from the selected magnetometer is greater than a predetermined threshold. If the selected magnetometer is greater than the predetermined threshold, the method proceeds to step 535. If the selected magnetometer is not greater than the predetermined threshold, the method proceeds to step 540.

At step 535, the system stores the position data of the magnetometer and indicates that a defect is likely present at the position. The position data may include axial position data (e.g., position along the axial length of the pipe) and/or radial position data (e.g., the radial position of the pipe over which the pipeline inspection tool is positioned).

At step 540, the system stores the position data of the magnetometer and indicates that a defect is likely not present at the position.

At step 545, the system determines if there are other magnetometers that have not yet been analyzed. If there are still some magnetometers that have not yet been analyzed, the method reverts back to step 525 to select a new magnetometer for analysis. If all of the magnetometers have been analyzed, the method proceeds to step 550.

At step 550, the pipeline inspection tool is moved to the next section of pipe to be examined and the method reverts back to the beginning.

From the foregoing, it will be appreciated that specific embodiments of the invention have been described herein for purposes of illustration, but that various modifications may be made without deviating from the scope of the invention. Accordingly, the invention is not limited except as by the appended claims.

I/We claim:

1. A handheld pipeline inspection tool for examining a section of piping, comprising:
a box having a bottom surface and a plurality of magnetometers disposed adjacent to the bottom surface;
a pad having an excitation coil disposed within the pad, wherein—
the pad is coupled to the box at the bottom surface,
the excitation coil is disposed adjacent to an outer perimeter of the pad, and
the excitation coil is arranged in a loop and the plurality of magnetometers are positioned within the loop.

2. The handheld pipeline inspection tool of claim 1, wherein the excitation coil comprises a plurality of loops.

3. The handheld pipeline inspection tool of claim 2 wherein the pad comprises a printed circuit board having conductive traces printed onto the printed circuit board, and wherein the plurality of loops is formed from the conductive traces.

4. The handheld pipeline inspection tool of claim 3, further comprising:
a power source disposed within the box and configured to generate a current, wherein the power source is operatively coupled to the excitation coil and configured to provide the current to the excitation coil in order to energize the excitation coil and wherein the excitation coil is configured to generate a magnetic field when it receives the current.

5. The handheld pipeline inspection tool of claim 4, wherein the generated magnetic field is configured to induce a magnetic field in the section of piping when the inspection tool is positioned over the section of piping, and wherein the array of magnetometers are configured to detect the induced magnetic field.

6. The handheld pipeline inspection tool of claim 3, wherein the plurality of loops comprises 125 loops.

7. The handheld pipeline inspection tool of claim 1 wherein each of the plurality of magnetometers is a vector magnetometer.

8. The handheld pipeline inspection tool of claim 1 wherein the plurality of magnetometers comprises 16 magnetometers arranged in a 1×16 array aligned along a midline of the pad.

9. A handheld pipeline inspection tool for inspecting a section of piping, comprising:
a pad comprising an excitation coil; and
a box having a bottom surface, wherein the pad is coupled to the box at the bottom surface, the box comprising:
a power source configured to generate a current, wherein the excitation coil is energized by the current; and
an array of magnetometers, wherein the array of magnetometers is configured to detect magnetic fields induced in the section of piping when the excitation coil is energized.

10. The handheld pipeline inspection tool of claim 9, wherein:
the magnetic fields induced in the section of piping comprise a first magnetic field,
the excitation coil is configured to generate a second magnetic field when the excitation coil is energized by the current, and
the second magnetic field is configured to induce the first magnetic field when the handheld pipeline inspection tool is arranged over the section of piping.

11. The handheld pipeline inspection tool of claim 10, the box further comprising:
a data acquisition and processing system operatively coupled to the plurality of magnetometers, wherein the plurality of magnetometers is configured to generate sensor data based on the detected first magnetic field and to provide the generated sensor data to the data acquisition and processing system, and wherein the data and processing system is configured to compare the generated sensor data to predetermined threshold data.

12. The handheld pipeline inspection tool of claim 11 wherein the data acquisition and processing system is configured to determine that the section of pipe includes at least one defect when the data and processing system determines that the generated sensor data is different from the predetermined threshold data.

13. The handheld pipeline inspection tool of claim 9 wherein the current is an alternating current.

14. The handheld pipeline inspection tool of claim 9 wherein the pad comprises a printed circuit board having conductive traces and.

15. The handheld pipeline inspection tool of claim 14 wherein the excitation coil comprises a plurality of loops and wherein each of the plurality of loops comprises the conductive traces.

16. A system for inspecting a section of piping, comprising:
an electronics box configured to output an alternating current, wherein the electronics box comprises a plurality of magnetometers arranged adjacent to a bottom surface of the electronics box;
a pad coupled to the bottom surface, wherein:
the pad includes an excitation coil configured to receive the alternating current,
the plurality of magnetometers is configured to detect magnetic fields induced in the section of piping when the excitation coil receives the alternating current,
the plurality of magnetometers are aligned along a midline of the pad, and
the excitation coil comprises at least one loop of conductive material centered on the midline.

17. The system of claim 16 wherein the at least one loop of conductive material is disposed adjacent to an outer perimeter of the pad.

18. The system of claim 17 wherein the plurality of magnetometers is completely surrounded by the at least one loop of conductive material.

19. The system of claim 16 wherein the pad comprises a printed circuit board having a plurality of conductive traces that form the at least one loop of conductive material.

20. The system of claim 16 wherein the at least one loop of conductive material comprises 125 loops of conductive material.
